(19) United States
(12) Patent Application Publication
(10) Pub. No.: US 2010/0183866 A1
(43) Pub. Date: Jul. 22, 2010

(54) METHOD FOR PRODUCING A PARTICLE-ARRANGED STRUCTURE

(76) Inventors: Akira FUJIMOTO, Kawasaki-Shi (JP); Tsutomu Nakanishi, Tokyo (JP); Shigeru Matake, Yokohama-Shi (JP); Koji Asakawa, Kawasaki-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/687,486

(22) Filed: Jan. 14, 2010

(30) Foreign Application Priority Data
Jan. 20, 2009 (JP) 2009-10163

(51) Int. Cl. B32B 5/16; B05D 3/12; B05D 5/12

(52) U.S. Cl. 428/323; 427/240; 427/241; 427/66

(57) ABSTRACT

The present invention provides a method for easily producing a particle-arranged structure. In the structure produced by the method, particles are regularly arranged. The method of the present invention comprises: preparing a dispersion comprising a solvent, a polymerizable compound dissolved in the solvent and particles insoluble and dispersed uniformly in the solvent; spin-coating the dispersion on a substrate so as to arrange the particles in the liquid phase of the dispersion; and then curing the polymerizable compound.

### CROSS-REFERENCE TO RELATED APPLICATIONS

This application is based upon and claims the benefit of priority from the prior Japanese Patent Application No. 2009-10163, filed on Jan. 20, 2009; the entire contents of which are incorporated herein by reference.

### BACKGROUND OF THE INVENTION

1. Field of the Invention

The present invention relates to a method for producing a structure in which fine particles are arranged.

2. Background Art

Hitherto, various methods have been known as techniques for arranging fine particles. For example, there are known methods utilizing sedimentation, electric field, capillary force and meniscus force (see, for example, K. Fukuda et al., Japanese Journal of Applied Physics, vol. 37 (1998), L508; M. Holgano et al., Langmuir, vol. 15 (1999), pp. 4701; Antony S. Dimitrov et al., Langmuir, vol. 12 (1996), pp. 1303; and J. D. Joannopoulos, Nature, vol. 414 (2001), pp. 257). Those methods enable to arrange particles three-dimensionally, but it is still difficult to arrange particles two-dimensionally and to form a layer having thickness corresponding to one particle (namely, mono-particle layer). Further, even when particles are arranged three-dimensionally, it is difficult to control how many layers the particles are stacked to form.

It is also disclosed (in JP-A 2007-510183 (KOKAI)) to arrange particles regularly by spin-coating a substrate or the like with a dispersion in which silica particles are dispersed in acrylic monomer. The disclosed method is based on the mechanism described below. In the spin-coating, stress is generated by rotation and first it acts on the acrylic monomer, which is viscous. The stress then acts on the silica particles dispersed in the acrylic monomer, to generate shear stress. Because of the shear stress, the particles are relatively densely arranged. In order to arrange the particles regularly, the highly viscous monomer is indispensable to this method. Accordingly, the dispersion itself has such high viscosity that a large amount of the monomer remains among the silica particles and consequently that the intervals among the particles in the same layer are 1.4 times as large as the particle size (diameter). This means that the particles are not closest-packed in the layer. On the other hand, however, the stacked layers are so closest-packed that the gap between the particles in adjacent layers is almost the same as the particle size. Therefore, even if this method is adopted, it is still difficult to place the particles in a complete three-dimensional regular arrangement. Further, since the acrylic monomer used in this method is viscous, the number of the layers cannot be controlled if the particles have sizes of less than a few hundred nanometers. In particular, it is difficult to arrange the particles in a small number of layers, and it is extremely difficult and it takes very long time to arrange them completely in a single layer.

### SUMMARY OF THE INVENTION

The present invention resides in a method for producing a particle-arranged structure, comprising:

preparing a dispersion comprising a solvent, a polymerizable compound dissolved in said solvent and particles insoluble and dispersed uniformly in said solvent;

spin-coating said dispersion on a substrate so as to arrange said particles in the liquid phase of the dispersion; and

curing said polymerizable compound.

The present invention also resides in a particle-arranged structure produced by:

preparing a dispersion comprising a solvent, a polymerizable compound dissolved in said solvent and particles insoluble and dispersed uniformly in said solvent;

spin-coating said dispersion on a substrate so as to arrange said particles in the liquid phase of the dispersion; and

curing said polymerizable compound.

The present invention further resides in a method for producing an organic electroluminescence device, comprising:

preparing a dispersion comprising a solvent, a polymerizable compound dissolved in said solvent and particles insoluble and dispersed uniformly in said solvent;

spin-coating said dispersion on a substrate having a metal film on the surface thereof, so as to arrange said particles in the liquid phase of the dispersion;

curing said polymerizable compound to form particle layers, and

forming an organic electroluminescence layer on said particle layers.

The present invention furthermore resides in a pattern formation method comprising:

preparing a dispersion comprising a solvent, a polymerizable compound dissolved in said solvent and particles insoluble and dispersed uniformly in said solvent;

spin-coating said dispersion on a substrate so as to arrange said particles in the liquid phase of the dispersion;

curing said polymerizable compound; and

etching the substrate by use of said particles thus arranged as a mask, so that the arrangement of said particles is transferred onto the substrate.

The present invention enables to produce a particle-arranged structure in which particles are regularly arranged two- or three-dimensionally. In the structure, the particles in the same layer can be so closest-packed that the intervals among them are almost the same as the particle size. Further, even in the case where two or more particle layers are formed, the stacked layers can be also closest-packed to form a three-dimensional particle arrangement having high regularity. In the present invention, the number of the stacked layers can be easily controlled by regulating the content of the solvent in the dispersion. According to the present invention, therefore, it is possible to form any of one to several layers. Further, even if the particles are as small as 100 nm or less in size, the method of the present invention enables to control the number of layers in which such fine particles are arranged. The present invention, therefore, makes it possible to easily produce a finer structure.

### BRIEF DESCRIPTION OF THE DRAWINGS

FIG. 1 is an scanning electron microscope of the particle-arranged structure produced in Example 1.

FIG. 2 is an scanning electron microscope of the particle-arranged structure produced in Example 2.

FIG. 3 is an scanning electron microscope of the particle-arranged structure produced in Example 4.

FIG. 4 is an scanning electron microscope of the particle-arranged structure produced in Example 9.

FIG. 5 is an scanning electron microscope of the particle-arranged structure produced in Example 11.

FIG. 6A is scanning electron microscope of the particle-arranged structure produced in Example 13, and FIG. 6B is an scanning electron microscope of the substrate surface etched by use of the produced structure as a mask.

### DETAILED DESCRIPTION OF THE INVENTION

Embodiments of the present invention are explained below.

The method for producing a particle-arranged structure according to one embodiment of the present invention enables to arrange particles regularly on a substrate. In the method, the particles are dispersed in a mixed medium comprising a solvent and a polymerizable compound. Since the particles constitute the resultant particle-arranged structure, their shapes must not change essentially in the mixed medium. The particles, therefore, must be insoluble in the solvent.

Further, since the particles are arranged by the action of gravity and of stress based on centrifugal force generated in spin-coating, they preferably have specific gravity larger than the mixed medium of the solvent and the polymerizable compound.

The particles are preferably made of, for example, metals such as gold, platinum, silver and copper; or oxides such as silica, titania, alumina, manganese oxide, yttria, zinc oxide, tin oxide and ITO. Among them, silica is most preferred in view of durability against the solvent and of particle shape. Although the particles can be made of organic materials such as resins, the materials in that case are restricted in consideration of specific gravity and of solubility in the solvent, as described above.

The particles have diameters properly selected depending on the use of the resultant particle-arranged structure, but they are generally 1 nm to 5000 nm, preferably 1 nm to 1000 nm. If the particle sizes are too large, the particles in the dispersion may precipitate to lower the dispersion stability and/or to impair regularity of the particle arrangement. Accordingly, it is necessary to take precautions in that case. Further, the diameters preferably distribute in such a narrow range that the particle arrangement can keep good regularity. The distribution of diameters, therefore, preferably has a coefficient of variation (hereinafter, often referred to as CV value) in the range of 10% or less. The CV value is calculated (in terms of %) according to the formula of:

(standard deviation of diameter distribution)/(average diameter of particles)×100. It is most preferred for the particle sizes to distribute in a mono-dispersion.

There is no particular restriction on the shape of the particles, but the particles are preferably isotropic enough to be regularly arranged. The less the particles are isotropic, the more difficult it is to control the regularity of particle arrangement. The particles are preferably spherical, cubic or octahedral, most preferably spherical in shape.

In the present invention, the solvent in which the particles are dispersed is so selected that it does not dissolve the particle but the polymerizable compound described later. Accordingly, the solvent is selected according to the kind of the particles and to that of the polymerizable compound. Examples of the solvent include esters, ketones, alcohols, ethers, and hydrocarbons. As described later, the solvent is preferably evaporated in spin-coating and hence is preferably volatile. In the present invention, the “volatile” means that the boiling point is not higher than 200° C., preferably than 160° C.

Examples of the volatile solvent include ethyl lactate, methyl lactate, ethyl acetate, cyclohexanone, acetone, methyl ethyl ketone, dibutyl ether, n-hexene, and toluene. These solvents can be used in combination of two or more.

The polymerizable compound used in the present invention has functions of increasing the viscosity of the dispersion comprising the particles and, at the same time, of controlling the stress acting on the particles in spin-coating. Further, after the particles are arranged, the compound is polymerized and thereby cured to fix the particles on the substrate. Accordingly, the compound also has a function of forming a particle-arranged structure.

In the present invention, the “polymerizable compound” means a compound having a polymerizable group. Examples of the polymerizable group include: generally known polymerizable groups such as acryloyl, methacryloyl, unsaturated bonds, and epoxy; and combinations of particular groups such as a combination of carboxyl and hydroxyl capable of undergoing condensation polymerization reaction, and a combination of amino and carboxyl. The polymerizable compound used in the present invention may contain two or more polymerizable groups in one molecule thereof.

As the polymerizable compound described above, various substances are known. In the present invention, the dispersion is preferably not too viscous in consideration of controlling the number of layers formed by relatively small particles, for example, having diameters of 100 nm or less. If the polymerizable compound itself has too large a molecular weight, the dispersion is liable to be too viscous. On the other hand, however, if the compound itself has too small a molecular weight, there is a fear that the polymerizable compound cannot transmit the stress generated by rotation to the particles and consequently that it may result in failure to arrange the particles regularly. Accordingly, it is also preferred for the polymerizable compound itself to have not too small a molecular weight. The polymerizable compound preferably has a weight average molecular weight of 300 to 1000. The polymerizable compound is not restricted to, what is called, a monomer, and may be an oligomer.

Examples of the polymerizable compound include: acrylic acid, methacrylic acid, vinyl alcohol, ethyl acrylate, methyl acrylate, ethyl methacrylate, vinyl acetate, and styrene, which are compounds having relatively small molecular weights; and trimethylol propane triacrylate, ethoxylized trimethylol propane acrylate, propoxylized glyceryl triacrylate, and tripropylene glycol diacrylate, which are compounds having relatively large molecular weights. Those polymerizable monomers or oligomers having relatively large molecular weights can be available from, for example, Sartomer Company, Inc. If the dispersion is too viscous, the effect of the present invention often cannot be fully obtained. However, since it is necessary to keep a certain degree of viscosity, a polymerizable compound having a reactively large molecular weight is preferably used in the present invention. Two or more polymerizable compounds can be used in combination.

The solvent and the polymerizable compound are preferably so selected in combination that the difference in solubility parameter between them is 2.0 (cal/cm³)^{1/2} or less. If the difference in solubility parameter is thus controlled, the particle layers are formed uniformly enough to increase regularity of the particle arrangement. The solubility parameter is referred to as SP value, and the SP values of the solvent and the polymerizable compound are essentially determined inherently according to their structures. Actually, however, since it is practically impossible to directly measure the SP values, they can be estimated from the structures of the substances. In the present invention, SP values described in “Polymer Handbook 4^{th} Edition” can be used.

The dispersion used in the present invention indispensably comprises the solvent, particles and polymerizable compound described above, and may further contain other components, if necessary. For example, the dispersion can optionally comprise a polymerization initiator for controlling polymerization reaction of the polymerizable compound or a dispersing agent for stabilizing the dispersing state of the particles.

The optimum viscosity of the dispersion depends on the sizes and specific gravity of the particles and on the conditions of spin-coating. Accordingly, the viscosity of the dispersion is not necessarily restricted, but is preferably 100 cP or less at the temperature in spin-coating.

In the method according to the present invention, the aforementioned dispersion is spin-coated on a substrate. There is no particular restriction on the substrate, and it is properly selected according to the use of the resultant particle-arranged structure. For example, if the particle-arranged structure is intended to be used as a mask in etching a semiconductor layer or the like, a substrate having the semiconductor layer formed thereon can be employed. In the case where the structure is intended to be used as a light-extraction layer of a light emitting device, a substrate having a metal film formed thereon can be employed.

There is no particular restriction on the conditions of spin-coating, and they can be properly selected from those of the conventional spin-coating generally performed.

After the spin-coating, the polymerizable compound is polymerized and thereby cured to fix the particles arranged on the substrate. For curing the compound, it may be heated to undergo thermal polymerization or may be exposed to light to undergo photopolymerization. The conditions of those polymerizations are properly selected according to the kind of the polymerizable compound and to the concentration of the compound in the dispersion.

In this way, it is possible to obtain a structure in which the particles are arranged on the substrate. If the dispersion contains the polymerizable compound in a large amount, intervals among the arranged particles are filled with a polymer, namely, with a resin derived from the polymerizable compound, to obtain a particle-resin structure. On the other hand, if the dispersion contains the polymerizable compound in a relatively small amount, voids are left in the intervals among the particles although adjacent particles are combined via the resin, and as a result, a particle-air structure can be obtained. Further, if the particles in the particle-resin structure are removed by dissolving or by ashing, an air-resin structure can be obtained. It is not completely revealed what mechanism works to arrange the particles regularly in the method for producing a particle-arranged structure according to one embodiment of the present invention. However, it is thought to be as follows.

In the method of the present invention, it is presumed that stress generated by rotation in spin-coating is transmitted by the polymerizable compound to the particles dispersed in the dispersion and consequently that the particles are gradually arranged by the stress. Unlike the method disclosed in JP-A 2007-510183 (KOKAI), the dispersion comprises the solvent in the method of the present invention. Because of that, the stress generated by rotation is moderated and hence properly applied to the polymerizable compound. Further, since the dispersion contains the solvent, capillary force acts among the particles when the solvent is evaporated in spin-coating. Furthermore, the solvent in the dispersion reduces the polymerizable compound occupying the intervals among the particles, so that the particles are closest-packed in the same layer and so that the intervals among the particles are almost as large as the particle size. In the case where the particles are stacked in two or more layers, the layers are also closest-packed to form a three-dimensional particle arrangement having higher regularity.

Further, in the method of the present invention, since the dispersion contains the solvent, the viscosity thereof is relatively low and accordingly the arrangement of the particles can be easily controlled in a large area.

Furthermore, in the method of the present invention, the content of the solvent in the dispersion can be changed to regulate the concentration of the polymerizable compound and thereby the number of the particle layers can be easily controlled. Thus, the present invention enables to easily control one to several layers of the particles. Meanwhile, according to the method disclosed in JP-A 2007-510183 (KOKAI), the number of the formed particle layers depends on conditions of spin-coating such as the rotation speed and the square root of the rotation time if the viscosity of the monomer is determined. Therefore, if the number of the particle layers is intended to decrease in that method, it is necessary to lengthen the rotation time. In contrast, however, since the number of the layers depends on the concentration of the dispersion in the method of the present invention, it is unnecessary to lengthen the rotation time. Further, since the method of the present invention utilizes not only the stress generated by rotation but also capillary force acting among the particles, the particles can be arranged in closest packing even if the size distribution thereof ranges widely.

The method disclosed in JP-A 2007-510183 (KOKAI) is only capable of producing a particle-acrylic resin structure in which intervals among the particles are filled with an acrylic resin or of producing an air-acrylic resin structure obtained by removing the particles from the above particle-acrylic resin structure. In contrast, however, since the solvent is employed, the method of the present invention is also capable of producing a particle-air structure in which intervals among the particles are filled almost with voids, namely, with air and with only a small amount of polymer needed to fix the particles.

The method of the present invention can be combined with conventionally known methods for producing an etching mask or for producing an organic electroluminescence device (hereinafter, referred to as organic EL device). For example, a substrate having a particle-arranged structure loaded thereon can be etched by use of the arranged particles as a mask, so as to etch a fine regular pattern. The substrate thus subjected to etching can be used as an etching mask for another etching or as an element such as a filter. It is also possible to form a light-emitting layer, for example, an organic EL layer, on the particle-arranged structure of the present invention, so as to manufacture a semiconductor light-emitting device. In that case, the particle-arranged structure produced by the method of the present invention functions as a light-extraction layer for contributing toward improving brightness of the light-emitting device. The reason why the particle-arranged structure of the present invention improves the brightness is thought to be because the particle-arranged structure functions as a diffraction grating. In manufacturing the above light-emitting device, it is possible to combine any conventionally known method with the method of the present invention for producing a particle-arranged structure.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

### Example

### Example 1

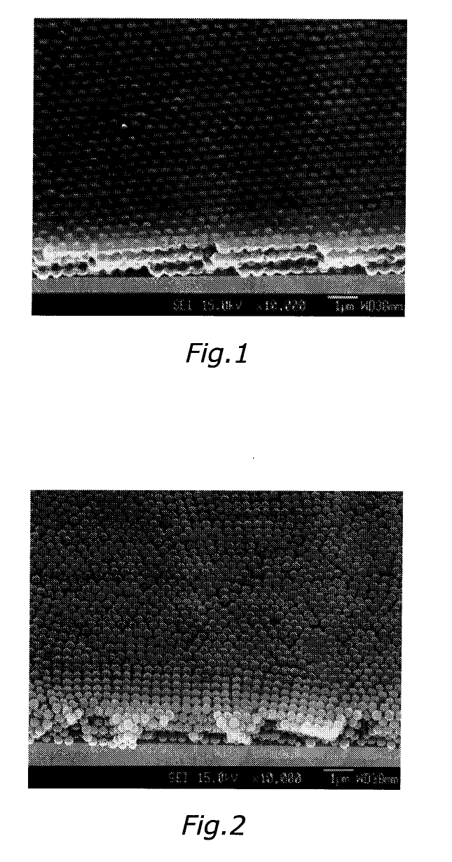

Silica particles of 400 nm diameter were dispersed in ethyl lactate. The concentration of the silica particles were adjusted at 20 wt %. To the mixture, acrylic monomer was added in such an amount that the volume ratio of silica particles:acrylic monomer might be 1:3 to prepare a dispersion. As the acrylic monomer, ethoxylated (6) trimethylolpropane triacrylate (hereinafter, referred to as E6TPTA) was used. The prepared dispersion was dropped onto a 3-inch silicon substrate and spin-coated at 2000 rpm for 60 seconds. After spin-coated, the substrate was baked at 110° C. for 60 seconds to remove the solvent completely. The substrate was then annealed for curing under nitrogen gas atmosphere at 150° C. for 1 hour. After annealing, it was verified that a three dimensional silica particle-air structure shown in FIG. 1 was formed.

### Example 2

Silica particles of 400 nm diameter were dispersed in ethyl lactate in a concentration of 80 wt %. To the mixture, E6TPTA was added and dissolved in ethyl lactate in such an amount that the volume ratio of silica particles:E6TPTA might be 1:1 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-air structure shown in FIG. 2 was formed. The formed structure had eight layers of the silica particles, and the intervals among the particles in the same layer were 440 nm and the gap between the particles in adjacent layers was 440 nm.

### Example 3

Silica particles of 400 nm diameter were dispersed in ethyl lactate in a concentration of 20 wt %. To the mixture, E6TPTA was added and dissolved in ethyl lactate in such an amount that the volume ratio of silica particles:E6TPTA might be 1:3 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-acrylic resin structure was formed. The formed structure had four layers of the silica particles, and the intervals among the particles in the same layer were 420 nm and the gap between the particles in adjacent layers was 420 nm.

### Example 4

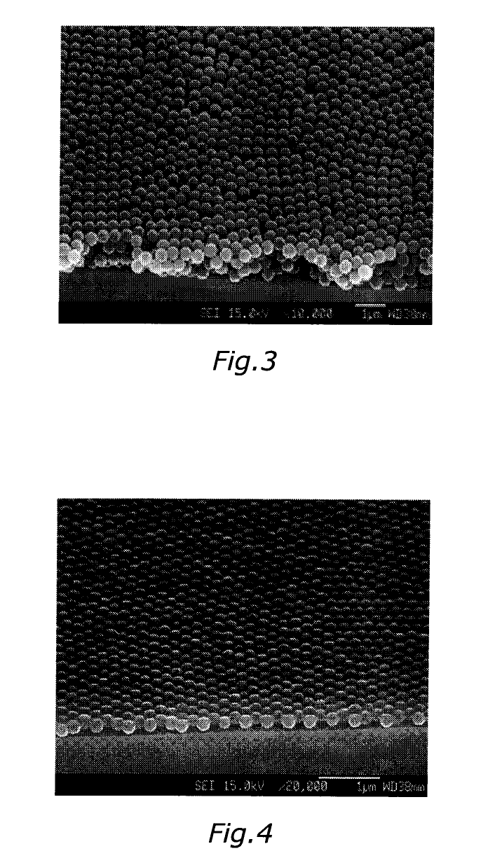

Silica particles of 400 nm diameter were dispersed in ethyl lactate in a concentration of 20 wt %. To the mixture, E6TPTA was added in such an amount that the volume ratio of silica particles:E6TPTA might be 1:0.7 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-air structure shown in FIG. 3 was formed. The formed structure had four layers of the silica particles, and the intervals among the particles in the same layer were 410 nm and the gap between the particles in adjacent layers was 410 nm.

### Example 5

Silica particles of 400 nm diameter were dispersed in ethyl lactate in a concentration of 20 wt %. To the mixture, E6TPTA was added in such an amount that the volume ratio of silica particles:E6TPTA might be 1:1.5 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour, to form a silica particle-acrylic resin structure. The formed structure had four layers of the silica particles, and the intervals among the particles in the same layer were 410 nm and the gap between the particles in adjacent layers was 410 nm. Since the acrylic monomer was incorporated in a relatively small amount as compared with the silica particles, there were observed voids at several places in the formed structure. Even so, however, the silica particles were arranged without problem.

### Example 6

Silica particles of 400 nm diameter were dispersed in cyclohexanone in a concentration of 20 wt %. To the mixture, E6TPTA was added in such an amount that the volume ratio of silica particles:E6TPTA might be 1:3 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-acrylic resin structure was formed. The formed structure had four layers of the silica particles, and the intervals among the particles in the same layer were 420 nm and the gap between the particles in adjacent layers was 420 nm.

### Example 7

Silica particles of 200 nm diameter were dispersed in ethyl lactate in a concentration of 20 wt %. To the mixture, E6TPTA was added in such an amount that the volume ratio of silica particles:E6TPTA might be 1:3 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-acrylic resin structure was formed. The formed structure had eight layers of the silica particles, and the intervals among the particles in the same layer were 220 nm and the gap between the particles in adjacent layers was 220 nm.

### Example 8

Silica particles of 100 nm diameter were dispersed in ethyl lactate in a concentration of 20 wt %. To the mixture, E6TPTA was added in such an amount that the volume ratio of silica particles:E6TPTA might be 1:3 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-acrylic resin structure was formed. The formed structure had 16 layers of the silica particles, and the intervals among the particles in the same layer were 120 nm and the gap between the particles in adjacent layers was 120 nm.

### Example 9

Silica particles of 200 nm diameter were dispersed in ethyl lactate in a concentration of 5 wt %. To the mixture, E6TPTA was added in such an amount that the volume ratio of silica particles:E6TPTA might be 1:3 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-acrylic resin structure in which the silica particles were arranged two-dimensionally as shown in FIG. 4 was formed. The formed structure had only a single layer of the silica particles, and the intervals among the particles in the layer were 220 nm.

### Example 10

Silica particles of 200 nm diameter were dispersed in ethyl lactate in a concentration of 8 wt %. To the mixture, E6TPTA was added in such an amount that the volume ratio of silica particles:E6TPTA might be 1:3 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-acrylic resin structure was formed. The formed structure had two layers of the silica particles, and the intervals among the particles in the same layer were 220 nm.

The results of Examples 7, 9 and 10 revealed that the number of the layers could be controlled only by changing the content of the solvent.

### Example 11

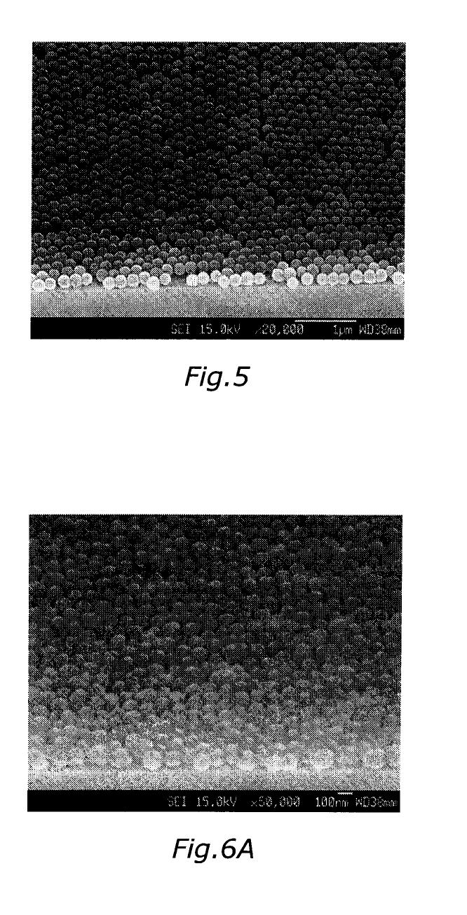

Silica particles of 200 nm diameter were dispersed in ethyl lactate in a concentration of 8 wt %. To the mixture, E6TPTA was added in such an amount that the volume ratio of silica particles:E6TPTA might be 1:0.5 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-air structure shown in FIG. 5 was formed. The formed structure had only a single layer of the silica particles, and the intervals among the particles in the layer were 210 nm.

### Example 12

Silica particles of 20 nm diameter were dispersed in ethyl lactate in a concentration of 1 wt %. To the mixture, E6TPTA was added in such an amount that the volume ratio of silica particles:E6TPTA might be 1:0.8 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-air structure was formed. The formed structure had only a single layer of the silica particles, and the intervals among the particles in the layer were 20 nm.

The above results revealed that even very fine particles could be arranged in a mono-particle layer by increasing the content of the solvent.

### Example 13

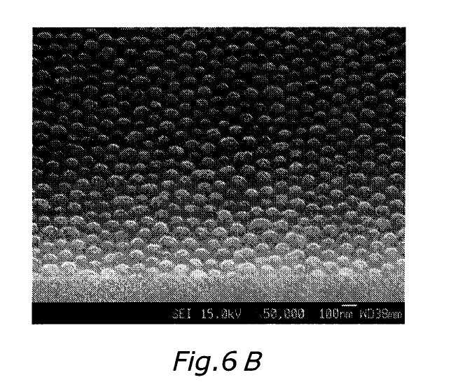

Silica particles of 100 nm diameter were dispersed in ethyl lactate in a concentration of 3 wt %. To the mixture, E6TPTA was added in such an amount that the volume ratio of silica particles:E6TPTA might be 1:3 to prepare a dispersion. The prepared dispersion was dropped onto a 3-inch silicon substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-acrylic resin structure shown in FIG. 6A was formed. The formed structure had only a single layer of the silica particles, and the intervals among the particles in the layer were 120 nm.

Subsequently, the silica particles thus arranged were used as a mask for etching which was carried out for 1 minute by means of a reactive ion etching (RIE) apparatus under the conditions of a CF₄ flow rate of 30 sccm, a pressure of 1.33 Pa (10 mTorr), and a power of 100 W. The etched depth was 50 nm (FIG. 6B). This procedure revealed that the mono-particle layer of the silica particles could be used as a mask for etching fabrication.

### Example 14

Silica particles of 400 nm diameter were dispersed in ethyl lactate in a concentration of 20 wt %. To the mixture, E6TPTA was added in such an amount that the volume ratio of silica particles:E6TPTA might be 1:0.7 to prepare a dispersion.

Independently, Ag was sputtered onto a glass substrate to form thereon a reflection mirror of 300 nm thickness. The prepared dispersion was thereafter dropped onto the substrate and spin-coated at 2000 rpm for 60 seconds. After spin-coated, the substrate was baked at 110° C. for 60 seconds and then annealed for curing under nitrogen gas atmosphere at 150° C. for 1 hour. After annealing, it was verified that a silica particle-air structure was formed. The formed structure had four layers of the silica particles, and the intervals among the particles in the same layer were 410 nm and the gap between the particles in adjacent layers was 410 nm.

Subsequently, SiN was deposited thereon by a plasma CVD method to form a SiN layer of 300 nm thickness for smoothing. Thereafter, ITO was deposited by sputtering to form an anode of 150 nm thickness. On the anode of ITO, N,N′-diphenyl-N,N′-bis(3-methylphenyl)-1-1′-bisphenyl-4,4′-di-amine was deposited by a vapor-deposition method to form a hole injection layer of 50 nm thickness. Then, tris-(8-hydroxy-quinoline)aluminum was further deposited thereon by a vapor-deposition method to form a luminescence layer of 100 nm thickness. Finally, ITO was again deposited by sputtering to form a cathode of 150 nm thickness. Thus, an organic EL device was produced. It was found that the organic EL device emitted light having a peak at 530 nm.

As a result of evaluating the obtained organic EL device, it was verified that the obtained device was so improved in brightness that its brightness was twice as large as that of a device produced without using the particle-arranged structure.

1. A method for producing a particle-arranged structure, comprising:
preparing a dispersion comprising a solvent, a polymerizable compound dissolved in said solvent and particles insoluble and dispersed uniformly in said solvent;
spin-coating said dispersion on a substrate so as to arrange said particles in the liquid phase of the dispersion; and
curing said polymerizable compound.

2. The method according to claim 1, wherein said particles are so arranged that they form a single layer on said substrate.

3. The method according to claim 1, wherein said particles are so arranged that they form two or more layers on said substrate.

4. The method according to claim 1, wherein said particles have diameters with a CV value of 10% or less.

5. The method according to claim 1, wherein the polymerizable compound has a molecular weight of 300 to 1000.

6. The method according to claim 1, wherein the volume mixing ratio of said polymerizable compound to said particles is in the range of 0.5 to 4.

7. The method according to claim 1, wherein said particles are made of oxides or metals.

8. The method according to claim 1, wherein the difference in solubility parameter between said solvent and said polymerizable compound is 2.0 (cal/cm³)^{1/2} or less.

9. A particle-arranged structure produced by:
preparing a dispersion comprising a solvent, a polymerizable compound dissolved in said solvent and particles insoluble and dispersed uniformly in said solvent;
spin-coating said dispersion on a substrate so as to arrange said particles in the liquid phase of the dispersion; and
curing said polymerizable compound.

10. A method for producing an organic electroluminescence device, comprising:
preparing a dispersion comprising a solvent, a polymerizable compound dissolved in said solvent and particles insoluble and dispersed uniformly in said solvent;
spin-coating said dispersion on a substrate having a metal film on its surface, so as to arrange said particles in the liquid phase of the dispersion therein;
curing said polymerizable compound to form particle layers, and
forming an organic electroluminescence layer on said particle layers.
